(19) United States
(12) Patent Application Publication
(10) Pub. No.: US 2014/0193941 A1
(43) Pub. Date: Jul. 10, 2014

(54) METHOD FOR MANUFACTURING SOLAR CELL

(71) Applicant: SAMSUNG SDI CO., LTD., Yongin-si (KR)

(72) Inventors: Min-Sung Kim, Yongin-si (KR); Min-Kyu Kim, Yongin-si (KR); Su-Yeon Kim, Yongin-si (KR); Yuk-Hyun Nam, Yongin-si (KR); Ku-Hyun Kang, Yongin-si (KR)

(73) Assignee: SAMSUNG SDI CO., LTD., Yongin-si (KR)

(21) Appl. No.: 14/088,296

(22) Filed: Nov. 22, 2013

Related U.S. Application Data
(60) Provisional application No. 61/751,207, filed on Jan. 10, 2013.

(51) Int. Cl. H01L 31/18; H01L 31/0216

(52) U.S. Cl. CPC H01L 31/1828; H01L 31/02168
USPC 438/72; 438/95

(57) ABSTRACT

A method for manufacturing a solar cell includes forming a first electrode on a substrate, removing a portion of the first electrode to form a first electrode opening, forming a light absorbing layer on the first electrode and in the first electrode opening, and applying a laser beam to the substrate to create an interface reaction between the first electrode and at least the light absorbing layer, thereby removing a portion of the light absorbing layer to form a light absorbing layer opening.

### CROSS-REFERENCE TO RELATED APPLICATION

This application claims priority to and the benefit of U.S. Provisional Application No. 61/751,207, filed on Jan. 10, 2013 in the U.S. Patent and Trademark Office, the entire content of which is incorporated herein by reference.

### BACKGROUND

(a) Field

The present invention relates to a method for manufacturing a solar cell.

(b) Description of the Related Art

In order to make a solar cell module, a process for forming a plurality of unit cells, each including an electrode and a light absorbing layer formed on a substrate, and accessing the unit cells in series is used. The electrodes and the light absorbing layer are appropriately patterned so that the unit cells are respectively divided and electrically accessed or coupled with each other, but the patterning process may deteriorate a characteristic of a completed solar cell by damaging the electrode, for instance, a lower or first electrode located between the substrate and the light absorbing layer.

The above information disclosed in this Background section is only for enhancement of understanding of the background of the invention, and therefore it may contain information that does not form the prior art that is already known in this country to a person of ordinary skill in the art.

### SUMMARY

A method for manufacturing a solar cell includes forming a first electrode on a substrate, removing a portion of the first electrode to form a first electrode opening, forming a light absorbing layer on the first electrode and in the first electrode opening, and applying a laser beam to the substrate to create an interface reaction between the first electrode and at least the light absorbing layer, thereby removing a portion of the light absorbing layer to form a light absorbing layer opening.

The interface reaction may include vaporization of selenium (Se) in the light absorbing layer.

The interface reaction may include vaporization of sulfur (S) in the light absorbing layer.

A second electrode may be formed on the light absorbing layer and in the light absorbing layer opening, and the laser beam may be applied to the substrate to create another interface reaction between the first electrode and at least the light absorbing layer, thereby removing another portion of the light absorbing layer and a corresponding portion of the second electrode to form a second electrode opening.

The light absorbing layer may include a compound of an element belonging to Group I of the Periodic Table, an element belonging to Group III of the Periodic Table and an element belonging to Group VI of the Periodic Table.

The light absorbing layer may include CuInSe, CuInSe₂, CuInGaSe, or CuInGaSe₂.

The light absorbing layer may include sulfur (S) and one of CuInSe, CuInSe₂, CuInGaSe, or CuInGaSe₂.

The second electrode may include BZO, ZnO, In₂O₃, or ITO.

An antireflective coating may be formed on the second electrode.

A buffer layer may be formed on the light absorbing layer prior to forming the second electrode.

The buffer layer may include CdS, ZnS, or In₂O₃.

An intermediate layer may be formed on the first electrode prior to forming the light absorbing layer.

The intermediate layer may include MoSe₂.

The laser beam may vaporize selenium (Se) in the intermediate layer.

The intermediate layer may be in a range of about 50 Å to about 200 Å thick.

The first electrode may be opaque.

The first electrode may include nickel (Ni), copper (Cu), gold (Au) or molybdenum (Mo).

Embodiments of the present invention provide a method for manufacturing a solar cell that reduces or minimizes damage to an electrode when a solar cell module is configured by patterning the electrode and the light absorbing layer of the solar cell.

According to the method for manufacturing a solar cell according to an example embodiment of the present invention, when a plurality of unit cells are formed on the substrate, damage to the electrodes forming the unit cells may be reduced (e.g., prevented) and the unit cells may be uniformly divided, thereby preventing a reduction or deterioration of efficiency of the manufactured solar cell.

Further, other patterns can be patterned by using the same laser beam, thereby reducing the production cost.

Additional aspects and/or characteristics of the invention will be set forth in part in the description which follows and, in part, will be obvious from the description or may be learned by practice of the invention.

### BRIEF DESCRIPTION OF THE DRAWINGS

FIG. 1 shows a cross-sectional view of a solar cell according to an embodiment of the present invention.

FIG. 2 to FIG. 7 show cross-sectional views of a process for manufacturing a solar cell according to an embodiment of the present invention.

FIG. 8 shows an image of a second electrode opening according to an embodiment of the present invention.

FIG. 9 shows an image of a second electrode opening according to a comparative process.

### DETAILED DESCRIPTION

The present invention will be described more fully hereinafter with reference to the accompanying drawings, in which example embodiments of the invention are shown. As those skilled in the art would realize, the described embodiments may be modified in various different ways, all without departing from the spirit or scope of the present invention.

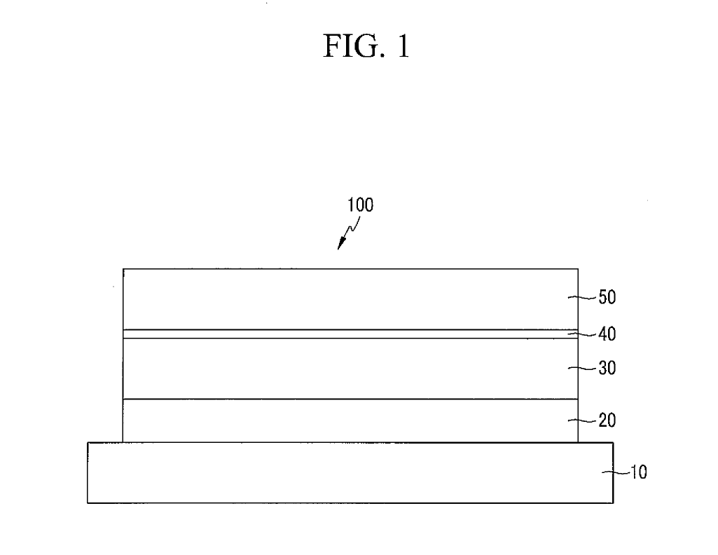

FIG. 1 shows a cross-sectional view of a configuration of a solar cell according to an embodiment of the present invention.

Referring to FIG. 1, the solar cell 100 includes a substrate 10, a first electrode 20 (e.g., a lower or opaque electrode layer), a light absorbing layer 30, a buffer layer 40, and a second electrode 50 (e.g., an upper or transparent electrode layer).

The solar cell 100 can be a compound semiconductor solar cell including CIS (Cu, In, and Se) or CIGS (Cu, In, Ga, and Se) in the light absorbing layer 30. The light absorbing layer 30 including the CIS or the CIGS will be exemplified hereinafter.

The substrate 10 is located at an outermost side (e.g., at one side) of the solar cell 100. That is, the substrate 10 is located farthest from the side to which light (e.g., sunlight) is applied (e.g., the side to which light first contacts). The substrate 10 can be formed of various suitable materials, including, for example, plate-type glass, ceramic, or film-type polymers.

The first electrode 20 is located or formed on the substrate 10. The first electrode 20 may be made of, for example, a metal with excellent optical reflective efficiency and adhesion to the substrate 10. For example, the first electrode 20 may include nickel (Ni), copper (Cu), gold (Au) or molybdenum (Mo). Molybdenum (Mo) has high electrical conductivity, forms an ohmic contact with the light absorbing layer 30, and is stable during a high-temperature heat treatment process for forming the light absorbing layer 30.

The light absorbing layer 30 (e.g., photoelectric conversation layer) is located or formed on the first electrode 20. The light absorbing layer 30 generates electrons and holes by using light energy that has been transmitted through the second electrode 50 and/or the buffer layer 40. The light absorbing layer 30 may include a compound of the element belonging to Group I of the Periodic Table, the element belonging to Group III of the Periodic Table and the element belonging to Group VI of the Periodic Table. The light absorbing layer 30 can include, for example, a chalcopyrite-based compound semiconductor selected from a group consisting of CuInSe, CuInSe₂, CuInGaSe, and CuInGaSe₂.

For example, the light absorbing layer 30 can be manufactured by performing a first process \textcircled{1} for forming a precursor layer by sputtering copper (Cu) and indium (In), or copper (Cu), indium (In), and gallium (Ga) on the first electrode 20, a second process \textcircled{2} for thermally depositing selenium (Se) on the precursor layer, and a third process \textcircled{3} for growing CIS (Cu, In, and Se) or CIGS (Cu, In, Ga, and Se) crystals using (e.g., by performing) a fast heat-treatment process for over one minute at a high temperature, for example, at a temperature that is greater than 550° C. Part of the selenium (Se) can be substituted with sulfur (S) to prevent evaporation of the selenium (Se) during the fast heat-treatment process. Therefore, an open voltage of the solar cell 100 can be increased by increasing an energy band gap of the light absorbing layer 30.

The buffer layer 40 can be located or formed on the light absorbing layer 30. The buffer layer 40 alleviates an energy band gap difference between the light absorbing layer 30 and the second electrode 50. Also, the buffer layer 40 eases a lattice constant difference between the light absorbing layer 30 and the second electrode 50 to increase the bond between the two layers 30 and 50. The buffer layer 40 may include, for example, cadmium sulfide (CdS), zinc sulfide (ZnS), or indium oxide (In₂O₃). The buffer layer 40 can be omitted, if necessary or desired.

The second electrode 50 is located or formed on the buffer layer 40. The second electrode 50 can be formed of, for example, a metal oxide including boron doped zinc oxide (BZO) with excellent light transmittance, zinc oxide (ZnO), indium oxide (In₂O₃), and indium tin oxide (ITO). The second electrode 50 has high electrical conductivity and high light transmittance. The second electrode 50 can have protrusions (e.g., rough protrusions) and/or depressions on the surface formed through an additional texturing process. In addition, an antireflective coating (e.g., an antireflection layer) can be further formed or located on or above the second electrode 50. Formation of the surface protrusions, depressions, and/or the antireflective coating on the second electrode 50 reduces reflection of external light to increase light (e.g., sunlight) transmitting efficiency toward the light absorbing layer 30.

The first electrode 20, the light absorbing layer 30, the buffer layer 40, and the second electrode 50 are identified by or separated into a plurality of unit cells on the substrate 10, and they are electrically coupled (e.g., electrically connected) with each other to form a module of the solar cell 100.

A method for manufacturing the solar cell according to an embodiment of the present invention will now be described.

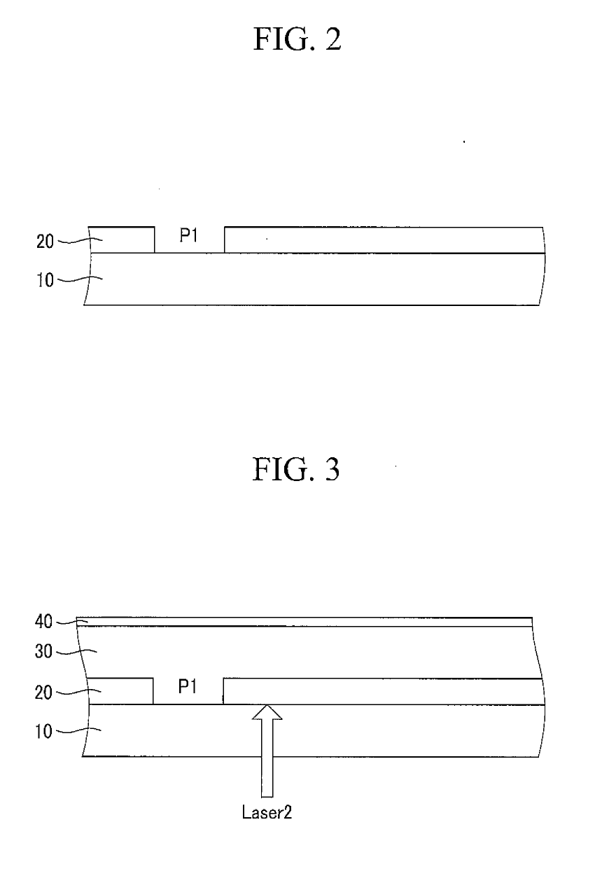

A first electrode 20 is formed or located on a first side of the substrate 10 with a thickness (e.g., predetermined thickness) using or through a method (e.g., predetermined method), such as sputtering, and the first electrode 20 is then divided into a plurality of smaller ones (e.g., cells). That is, the first electrode 20 is patterned at a position (e.g., predetermined position) and is divided into a plurality of smaller ones (e.g., cells) by a dividing method and/or device, such as first laser beams (Laser1) (not shown). A first electrode opening (P1) (e.g., a first pattern) (refer to FIG. 2) is formed in the division (or divisions) (e.g., openings) of the first electrode 20.

A light absorbing layer 30 and a buffer layer 40 are formed with a thickness (e.g., predetermined thickness) on the first electrode 20. That is, the light absorbing layer 30 is filled or formed at the top of the first electrode 20 and at the first electrode opening (P1) (refer to FIG. 3) (e.g., in an area between the first electrode 20 and the first electrode 20).

A second patterning process is performed on the light absorbing layer 30 and the buffer layer 40. As shown in FIG. 3, the second patterning process for the light absorbing layer 30 and the buffer layer 40 is performed by second laser beams (Laser2) that are directed at or applied to a second side of the substrate 10 that is opposite the first side of the substrate 10 and in a direction that is parallel to a direction from the light absorbing layer 30 towards the buffer layer 40.

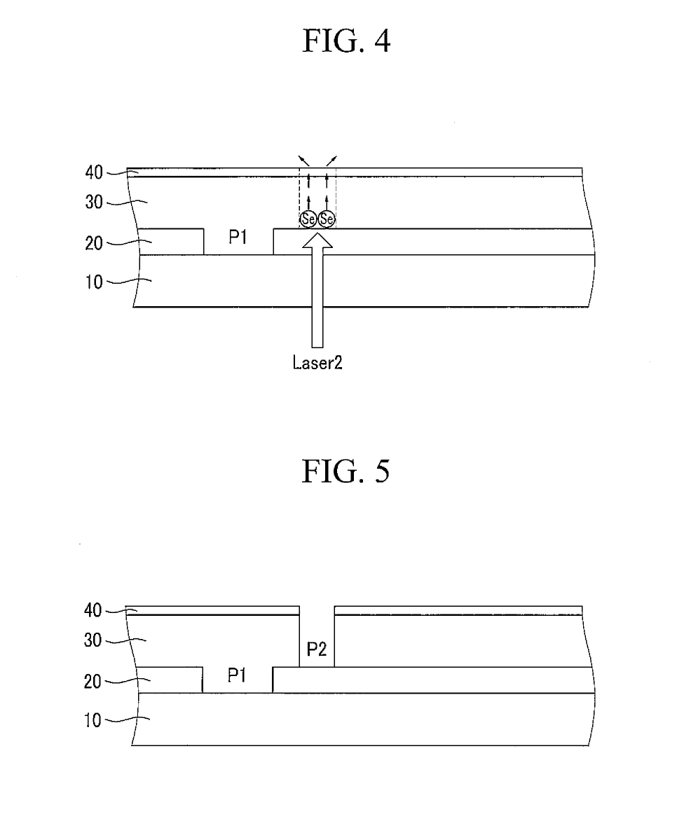

When the second patterning process is performed on the light absorbing layer 30 and the buffer layer 40 by using the second laser beams (Laser2) provided to the substrate 10, the first electrode 20 is heated by the laser beams, selenium (Se) and/or sulfur (S) is vaporized from an interface between the first electrode 20 and the light absorbing layer 30, and the light absorbing layer 30 is removed or lifted off from the first electrode 20 according to a pressure generated by the vaporization (refer to FIG. 4).

In one embodiment, the second patterning is performed using the vaporization of selenium (Se) caused by energy (e.g., heat energy) of the laser beams. Therefore, the second laser beams (Laser2) for the second patterning should have or be calibrated to have an energy (e.g., an appropriate energy) that does not ablate (e.g., damage or remove) the first electrode 20 but induces vaporization of selenium (Se) and/or sulfur (S).

Further, vaporization of selenium (Se) can use (e.g., can occur in or at) an intermediate layer (e.g., a MoSe₂ layer) formed or located between the first electrode 20 and the light absorbing layer 30. Here, the intermediate layer can be in a range of 50 Å to 200 Å thick.

Due to the interface reaction, the second patterning process can be performed without damaging the first electrode 20 and can prevent the light absorbing layer 30 from remaining at (e.g., on) the lower electrode 20 in a light absorbing layer opening (P2) (e.g., can remove the light absorbing layer 30 from the lower electrode 20 to form a light absorbing layer opening (P2)).

Therefore, as shown in FIG. 5, the light absorbing layer 30 and the buffer layer 40 can be divided into a plurality of smaller ones (e.g., cells) according to the light absorbing layer opening (P2) (e.g., second pattern) formed at a position (e.g., a predetermined position) different from the first electrode opening (P1).

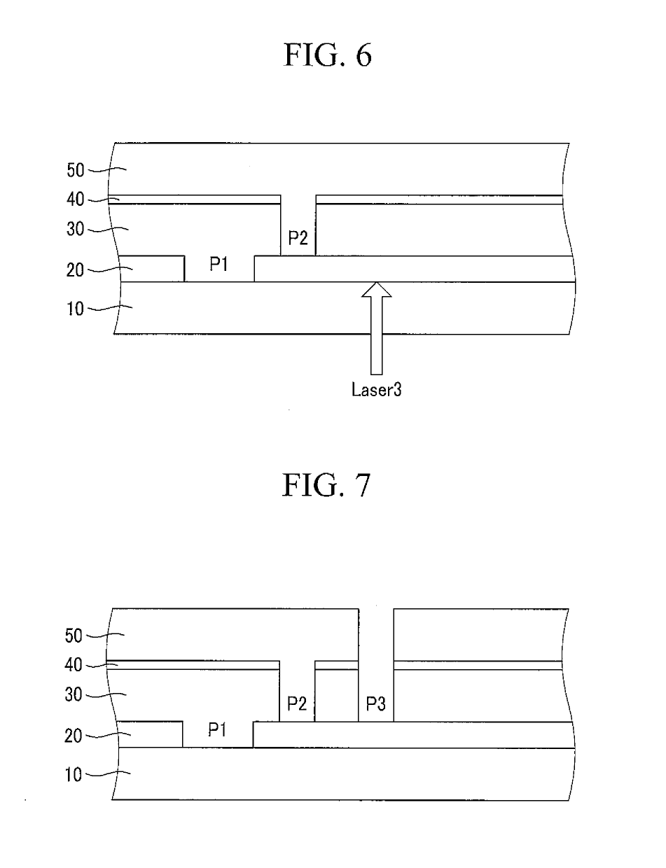

A second electrode 50 is formed with a thickness (e.g., predetermined thickness) on the buffer layer 40. That is, the second electrode 50 is filled or formed on the top side of the buffer layer 40 and at the light absorbing layer opening (P2) (refer to FIG. 6) (e.g., in an area between the light absorbing layer 30/the buffer layer 40 and the light absorbing layer 30/the buffer layer 40).

A third patterning process is performed on the light absorbing layer 30, the buffer layer 40, and the second electrode 50. As shown in FIG. 6, a third patterning process is performed by third laser beams (Laser3) provided to or directed at the substrate 10 in a manner similar to that of the second patterning process. The second laser beams (Laser2) for the second patterning process can be used as the third laser beams (Laser3) for the third patterning process.

By irradiation or application of the third laser beams (Laser3), an interface reaction is generated at the interface of the first electrode 20 and the light absorbing layer 30 on a third patterning part, and, in a manner similar to that of the second patterning process, the light absorbing layer 30 is removed or lifted off from the first electrode 20. In addition to the light absorbing layer 30, corresponding portions of the buffer layer 40 and the second electrode 50 are removed, and a second electrode opening (P3) (e.g., a third pattern) is formed on the first electrode 20 (refer to FIG. 7) at a position (e.g., a predetermined position) different from the first electrode opening (P1) and the light absorbing layer opening (P2).

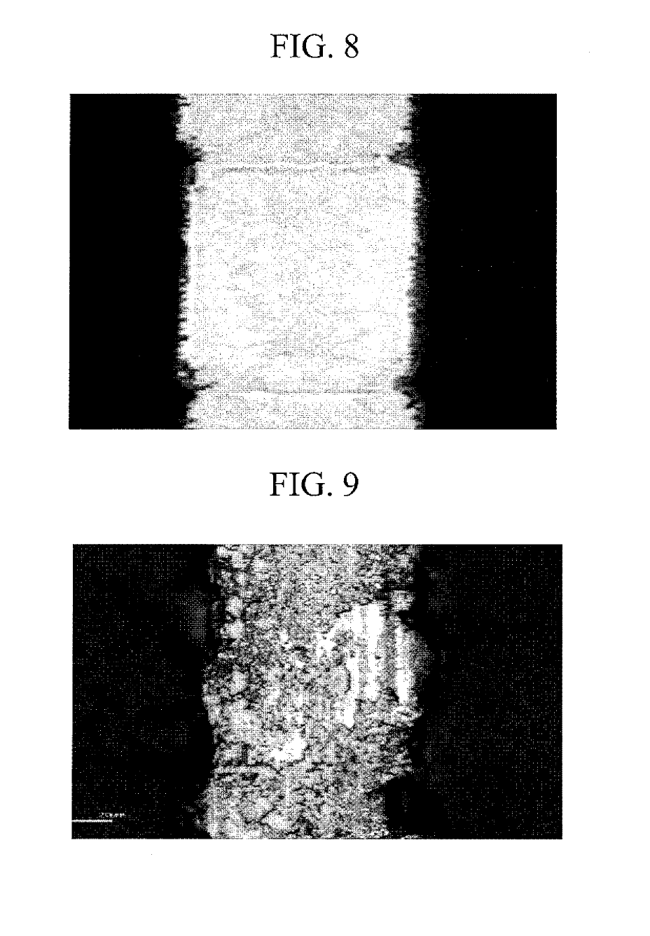

FIG. 8 shows an image of a second electrode opening (P3) according to an embodiment of the present invention, and FIG. 9 shows an image of a second electrode opening (P3) according to a comparative example of a related process.

The comparative example shown in FIG. 9 shows a case in which the second electrode opening is formed by using a mechanical tool, such as a cutting wheel or a knife, applied in a direction from the second electrode toward the substrate.

As can be seen in FIGS. 8 and 9, the embodiment of the present invention shown in FIG. 8 forms smoother edges along the periphery of the second electrode opening (P3) compared to the comparative example shown in FIG. 9.

Further, it can be seen that little or no material (e.g., film) is left on the first electrode without ablating (e.g., removing or destroying) the first electrode.

Through the above-described processes, a plurality of unit cells of the solar cell are electrically accessed (e.g., electrically coupled) in series on the substrate 10.

While example embodiments of the present invention have been described herein, it is to be understood that the invention is not limited thereto, but is intended to cover various modifications and equivalent arrangements included within the spirit and scope of the appended claims, description, drawings, and their equivalents.

What is claimed is:

1. A method for manufacturing a solar cell, the method comprising:
forming a first electrode on a substrate;
removing a portion of the first electrode to form a first electrode opening;
forming a light absorbing layer on the first electrode and in the first electrode opening; and
applying a laser beam to the substrate to create an interface reaction between the first electrode and at least the light absorbing layer, thereby removing a portion of the light absorbing layer to form a light absorbing layer opening.

2. The method of claim 1, wherein the interface reaction comprises vaporization of selenium (Se) in the light absorbing layer.

3. The method of claim 1, wherein the interface reaction comprises vaporization of sulfur (5) in the light absorbing layer.

4. The method of claim 1, further comprising forming a second electrode on the light absorbing layer and in the light absorbing layer opening, and
applying the laser beam to the substrate to create another interface reaction between the first electrode and at least the light absorbing layer, thereby removing another portion of the light absorbing layer and a corresponding portion of the second electrode to form a second electrode opening.

5. The method of claim 4, wherein the light absorbing layer comprises a compound of an element belonging to Group I of the Periodic Table, an element belonging to Group III of the Periodic Table and an element belonging to Group VI of the Periodic Table.

6. The method of claim 4, wherein the light absorbing layer comprises CuInSe, CuInSe₂, CuInGaSe, or CuInGaSe₂.

7. The method of claim 4, wherein the light absorbing layer comprises sulfur (S) and one of CuInSe, CuInSe₂, CuInGaSe, or CuInGaSe₂.

8. The method of claim 4, wherein the second electrode comprises BZO, ZnO, In₂O₃, or ITO.

9. The method of claim 4, the method further comprising forming an antireflective coating on the second electrode.

10. The method of claim 4, the method further comprising forming a buffer layer on the light absorbing layer prior to forming the second electrode.

11. The method of claim 10, wherein the buffer layer comprises CdS, ZnS, or In₂O₃.

12. The method of claim 1, the method further comprising forming an intermediate layer on the first electrode prior to forming the light absorbing layer.

13. The method of claim 12, wherein the intermediate layer comprises MoSe₂.

14. The method of claim 12, wherein the laser beam vaporizes selenium (Se) in the intermediate layer.

15. The method of claim 12, wherein the intermediate layer is in a range of about 50 Å to about 200 Å thick.

16. The method of claim 1, wherein the first electrode is opaque.

17. The method of claim 1, wherein the first electrode comprises nickel (Ni), copper (Cu), gold (Au) or molybdenum (Mo).
